(19) United States
(12) Patent Application Publication
(10) Pub. No.: US 2024/0395787 A1
(43) Pub. Date: Nov. 28, 2024

(54) INTEGRATED CIRCUIT WITH STACKED INTERPOSER

(71) Applicant: Microsoft Technology Licensing, LLC, Redmond, WA (US)

(72) Inventors: Rahul Agarwal, Livermore, CA (US); Andrew Jefferson Read, Sunnyvale, CA (US); Sriram Srinivasan, Chandler, AZ (US)

(21) Appl. No.: 18/476,029

(22) Filed: Sep. 27, 2023

Related U.S. Application Data
(60) Provisional application No. 63/504,657, filed on May 26, 2023.

(51) Int. Cl. H01L 25/18; H01L 23/00; H01L 23/522; H01L 25/00

(52) U.S. Cl. CPC H01L 25/18; H01L 23/5226; H01L 24/08; H01L 24/16; H01L 24/80; H01L 24/81; H01L 25/50; H01L 2224/08145; H01L 2224/16146; H01L 2224/80895; H01L 2224/80896; H01L 2224/81801

(57) ABSTRACT

Embodiments of the present disclosure include stacked interposers, electronic circuits using stacked interposers, and techniques for manufacturing stacked interposers. In some embodiments, one or more interposers of the stacked interposers comprise capacitors. The capacitors may be coupled to power terminals of an integrated circuit. In some embodiments, stacked interposers comprise electrical connections in a metallization layer of a silicon integrated circuit. Electrical connections of different interposers may be coupled together using vias. In other embodiments, interposers are coupled together using solder bumps.

### RELATED APPLICATIONS

This Application claims the benefit of priority to U.S. Provisional Patent Application No. 63/504,657 filed May 26, 2023, the contents of which are hereby incorporated herein by reference.

### BACKGROUND

The present disclosure relates generally to integrated circuits, and in particular, to integrated circuits with a stacked interposer.

Integrated circuits with digital processors and other electronic components are processing increasingly growing amounts of data. This growth in processing power has led to an increase in power consumption. As the power consumption in electronic systems increases, the higher power may require capacitors near or in an integrated circuit to limit supply bounce and meet power integrity specifications, for example. Existing artificial intelligence super computers (ASICs) and other compute products are struggling with power management issues, and in some cases lowering the performance of the product to meet power requirements.

The present disclosure provides techniques for improving power delivery to improve the performance of integrated electronic systems.

### BRIEF DESCRIPTION OF THE DRAWINGS

FIG. 1 illustrates an example stacked interposer according to an embodiment.

FIG. 2A illustrates a method of manufacturing a stacked interposer according to an embodiment.

FIG. 2B illustrates a method of manufacturing a stacked interposer according to an embodiment.

FIG. 3 illustrates an example stacked interposer according to another embodiment.

FIG. 4 illustrates an example stacked interposer according to yet another embodiment.

### DETAILED DESCRIPTION

Described herein are techniques for packaging integrated circuits using interposers. In the following description, for purposes of explanation, numerous examples and specific details are set forth in order to provide a thorough understanding of some embodiments. Various embodiments as defined by the claims may include some or all of the features in these examples alone or in combination with other features described below and may further include modifications and equivalents of the features and concepts described herein.

Features and advantages of the present disclosure include hybrid bonding multiple interposers to expand the capabilities of the interposer. In one embodiment, an integrated passive devices (IPD) wafer comprising capacitors (e.g., embedded deep trench capacitors, “eDTC”) is bonded to an interposer wafer to significantly increase the amount of capacitance available to a System on Chip (SoC). This can increase the amount of capacitance to which SoC has access compared to existing solutions without any change on SoC itself, for example.

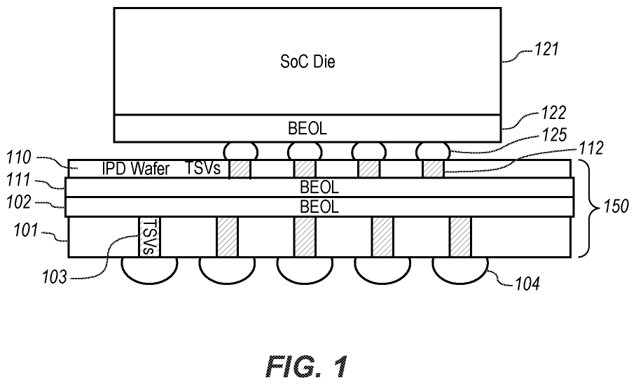

FIG. 1A illustrates an example stacked interposer according to an embodiment. In this example electronic system, a first integrated circuit (IC) 121 (e.g., an SoC) comprises one or more processors and a first plurality of bond pads coupled to a first plurality of solder bumps 125. IC 121 may include metallization layers 122, sometimes referred to as back end of line (BEOL), which may comprise a second portion of IC fabrication where the individual devices (transistors, capacitors, resistors, etc.) get interconnected with wiring on the wafer, such as copper metallization layers. Features and advantages of the present disclosure include a stacked interposer 150 comprising pads coupled solder bumps 125. Stacked interposer 150 comprises first and second integrated circuits (ICs) 101 and 110 (e.g., interposers) comprising electrical connections 102 and 111 (e.g., BEOLs), respectively. IC 101 comprises an interposer including vias 103 (e.g., through silicon vias, TSVs) to couple electrical connections 102 to solder bumps 104. IC 110 includes integrated passive devices (IPDs), such as capacitors (not shown), for example, which may be coupled together by electrical connections 111. IC 110 includes TSVs 112 coupled between electrical connections 111 and solder bumps 125. Connections 102 and 111 at the interface between ICs 101 and 110 may be coupled together using additional vias (illustrated below) on the bonded surface of ICs 101 and 110, for example. The stacked interposer 150 forms new interposer on which an SOC 121 can be stacked using chip on wafer on substrate with silicon interposer (CoWoS_S) process, for example. Advantageously, IC 110 comprising integrated capacitors may increase capacitance available to an IC 121 mounted on the stacked interposer. While interposer IC 101 may comprise some capacitors (not shown), the addition of a second interposer with integrated deep trench capacitors, for example, advantageously increases the available capacitance to ICs mounted on the stacked interposer. For example, capacitors on the interposer IC 110 may be coupled to power supply terminals of IC 121, thereby improving power delivery capabilities of the composite device.

FIG. 1B illustrates an electrical connection according to an embodiment. In some embodiments, power terminals of an integrated circuit may be coupled to capacitors in a stacked interposer to improve power delivery to the IC. For instance, power terminals may include one or more power supply terminals, V+, and one or more ground terminals, Gnd. V+ and Gnd power terminals of integrated circuit 121 may be coupled to external V+ and Gnd received, for example, over a printed circuit board (PCB). The power terminals may be coupled one or more bond pads 131a-b (e.g., through solder bumps, not shown) on a first lower surface of the stacked interposer comprising interposers 101 and 110. Pads 131 of interposer 101 are coupled to one or more through silicon vias 103a-b, which are in turn coupled to one or more electrical connections (e.g., metallizations) 102a-b. Metallizations 102a-b are in turn coupled to vias 161a-b at the upper surface of interposer 101. Vias 161a-b are bonded to vias 160a-b at the lower surface of interposer 110. Vias 160a-b are coupled to one or more electrical connections (e.g., metallizations) 111a-b interposer 110. Electrical connections 111b and 111a may be part of many electrical connections, including vias between electrical connection layers, for example. In this example, electrical connection 111a (e.g., V+) is coupled to one terminal of a capacitor 180 and another electrical connection 111b (e.g., Gnd) is coupled to another terminal of capacitor 180. Capacitor 180 is shown here in schematic form between connections 111a and 111b, but it is to be understood that capacitors would typically be formed below the metal layers as is known to those skilled in the art. Connections 111a-b are coupled to through silicon vias 112a-b, respectively, and to bond pads on the upper surface of interposer 110. Pads 130a-b are, in turn, coupled to V+ and Gnd connections of IC 121 through solder bumps 125a-b.

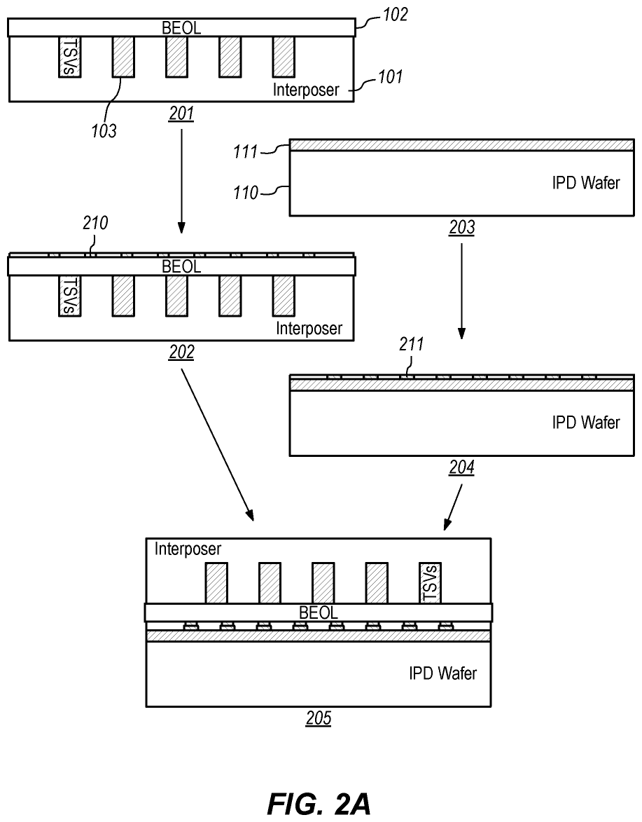

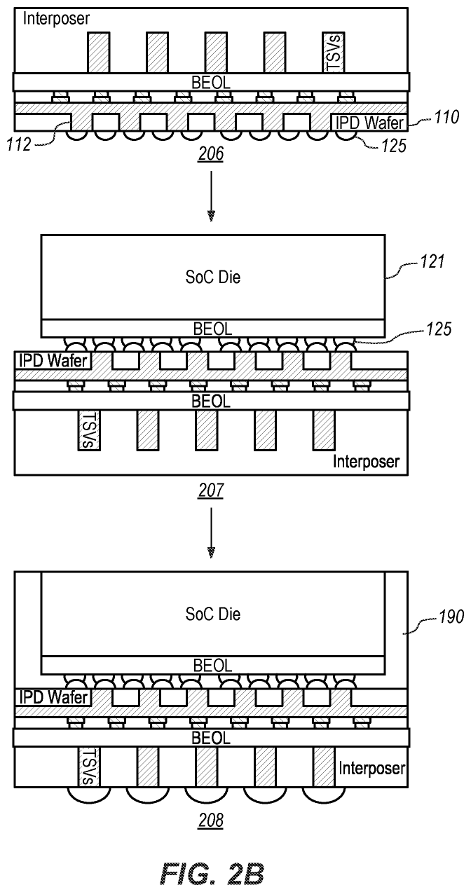

FIG. 2A illustrates a method of manufacturing a stacked interposer according to an embodiment. Forming an interposer is illustrated at 201 and 202. At 201, through silicon vias 103 and electrical connections are formed in interposer 101. In some embodiments, interposer 101 may comprise integrated capacitors, such as embedded deep trench capacitors, for example. At 202, vias 210 are formed. These vias may be formed as bond pads, for example on a first surface of interposer 101 by forming an oxide, etching through the oxide to the electrical connections, and depositing metal (plating), and performing a polish on the surface, for example. Forming the other interposer 110 (e.g., an integrated passive device interposer, IPD) is shown at 203 and 204. At 203, capacitors and electrical connections 111 are formed in the integrated passive device 110. Capacitors may be embedded deep trench capacitors, for example. At 204, vias 211 are formed on a first surface of the integrated passive device 110. At 205, the vias 210 on the first surface of the interposer 101 are bonded to the vias 211 on the first surface of the integrated passive device 110.

FIG. 2B further illustrates a method of manufacturing a stacked interposer according to an embodiment. In this example, a portion of a second surface of the integrated passive device substrate is removed, and vias are formed in the second surface. For example, at 206, the IPD 110 may be grinded to remove a portion of the IPD. Vias 112 are formed by etching the IPD, depositing conductive material (e.g., metal plating), and using chemical mechanical polishing to establish the vias (e.g., through silicon vias, TSV). At 207, an integrated circuit 121 is coupled to the vias in the stacked interposer using solder bumps 125. The ICs and stacked interposer may be covered (partially or completely) in molding compound 190 at 208.

One advantage of the presently disclosed techniques may include no required changes to the baseline SOC die/design, for example. Accordingly, the same SOC die can be used on a standard interposer and a stacked interposer disclosed herein. Additionally, the same baseline SOC design can be used in 2D or 2.5D packages by using bump conversion methods, such as 2D flip chip using standard bumps or 2.5D flip chip (CoWoS) with microbumps, for example. In various embodiments, the interposer used in the stacked interposer may be an active and/or passive interposer (e.g., with active or passive components). Additionally, an IPD wafer can be just IPD wafer or can have functionality built into it. The IPD wafer can also have some of interposer routing to enable more routing layers, for example. Various embodiments may mix and match of various IP blocks such as switches, accelerators, cache, and memory on the interposer, IPD, or on top of a stacked interposer, for example.

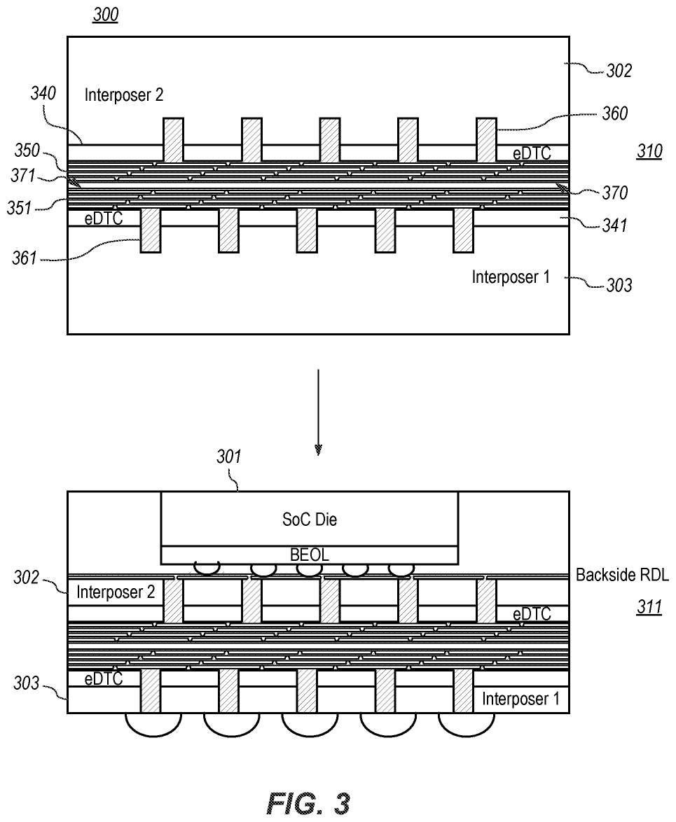

FIG. 3 illustrates an example stacked interposer according to another embodiment. Various embodiments of stacked interposers may include stacking interposers to obtain more electrical connections, more passive devices, or various combinations thereof. For example, some applications may benefit from more routing layers, which are increasing to enable higher bandwidth for device to device (D2D) and high bandwidth memories (HBM), for example.

In various embodiments, the present disclosure further includes an electronic circuit 301 comprising a stacked interposer 300. Stacked interposer 300 comprises a first interposer integrated circuit 302 comprising electrical connections 350 proximate to a first surface 370 of the first interposer integrated circuit 302 and vias 360 (e.g., TSVs). Stacked interposer 300 further comprises a second interposer integrated circuit 303 comprising electrical connections 351 proximate to a first surface 371 of the second interposer integrated circuit 303, and vias 361. At step 310, first and second interposer integrated circuits 302-303 are coupled together along surfaces 370-371 to form stacked interposer 300, and the first and second plurality of electrical connects 350-351 are coupled to a plurality of integrated circuits (e.g., SoC 301) bonded on top of stacked interposer 300. In some embodiments, interposer 302 and 303 may include embedded capacitors (eDTC) 340 and 341, respectively, to further improve power delivery capabilities.

An electronic circuit comprising a stacked interposer is illustrated at 311. Stacked interposer comprises a first integrated circuit 301 (e.g., SoC) comprising a first plurality of pads coupled to a first plurality of solder bumps. The stacked interposer comprises a second plurality of pads coupled the first plurality of solder bumps of the SoC, the stacked interposer further comprising a first interposer having, formed in a first surface of the first interposer, a first plurality of electrical connections and a first plurality of through silicon vias coupled to the first plurality of solder bumps; and a second interposer having, formed in a first surface of the second interposer, a second plurality of electrical connections and a second plurality of through silicon vias. A second plurality of solder bumps are coupled to the second plurality of through silicon vias.

Advantages of such embodiments include enabling denser and high capacity eDTC. Interposer folding using hybrid bonding can address both of these concerns.

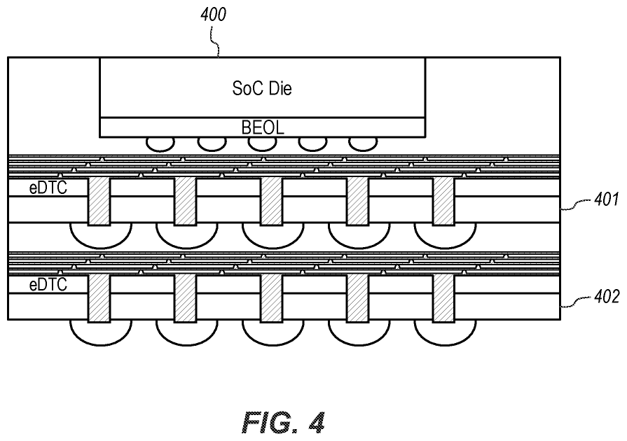

FIG. 4 illustrates an example stacked interposer according to yet another embodiment. In this example, an electronic circuit 400 comprises a stacked interposer. The stacked interposer comprises a first interposer having, formed in a first surface of the first interposer, a first plurality of electrical connections and a first plurality of through silicon vias coupled to a first plurality of solder bumps; and a second interposer having, formed in a first surface of the second interposer, a second plurality of electrical connections and a second plurality of through silicon vias coupled to a second plurality of solder bumps. The first plurality of solder bumps is bonded to the first surface of the second interposer and coupled to at least a portion of the second plurality of electrical connections of the second interposer. This approach may give products advantageous modularity, for example.

### FURTHER EXAMPLES

Each of the following non-limiting features in the following examples may stand on its own or may be combined in various permutations or combinations with one or more of the other features in the examples below. In various embodiments, the present disclosure may be implemented as an electronic circuit, system, or method.

In one embodiment, the present disclosure includes an electronic circuit comprising: a first integrated circuit comprising one or more processors and a first plurality of pads coupled to a first plurality of solder bumps; a stacked interposer comprising a first plurality of pads coupled the first plurality of solder bumps, the stacked interposer further comprising: a second integrated circuit comprising: a first plurality of electrical connections; and a first plurality of though silicon vias coupled between the first plurality of pads and the plurality of electrical connections; and a first plurality of vias coupled to the plurality of electrical connections; and a third integrated circuit comprising: a second plurality of electrical connections; a second plurality of vias coupled to the first plurality of vias of the second integrated circuit; and a second plurality of through silicon vias coupled between the second plurality of electrical connections and a second plurality of pads.

In one embodiment, the second integrated circuit further comprises a plurality of capacitors.

In one embodiment, a plurality of capacitors is coupled to power supply terminals of the first integrated circuit.

In one embodiment, at least one power supply terminal of the first integrated circuit is coupled to one or more of the second plurality of pads, one or more of the second plurality of through silicon vias, one or more electrical connections of the second plurality of electrical connections, one or more of the second plurality of vias, one or more of the first plurality of vias, one or more of the first plurality of electrical connections, one or more of the plurality of capacitors, one or more of the first plurality of through silicon vias, and one or more of the first plurality of solder bumps.

In one embodiment, the plurality of capacitors comprises one or more integrated deep trench capacitors.

In one embodiment, the third integrated circuit further comprises a second plurality of capacitors.

In one embodiment, the first integrated circuit is a system on a chip.

In another embodiment, the present disclosure includes a method of manufacturing an electronic circuit comprising: forming a first interposer comprising the steps of: forming through silicon vias in the first interposer; and forming vias on a first surface of the first interposer; forming a second interposer comprising the steps of: forming electrical connections in the second interposer; and forming vias on a first surface of the second interposer; bonding the vias on first surface of the first interposer to the vias on the first surface of the second interposer; removing a portion of a second substrate surface of the second interposer; forming through silicon vias in the second substrate surface of the second interposer; coupling an integrated circuit to the through silicon vias of the second interposer using solder bumps.

In one embodiment, the method further comprising: after forming through silicon vias in the second surface of the second interposer, removing a portion of a second substrate surface of the first interposer; and forming second solder bumps on the second substrate surface of the first interposer.

In one embodiment, forming the second interposer comprises forming a plurality of capacitors.

In one embodiment, the plurality of capacitors is coupled to power terminals of the integrated circuit.

In one embodiment, at least one power terminal of the integrated circuit is electrically coupled to one or more through silicon vias in the first interposer, one or more vias on the first surface of the first interposer, one or more vias on the first surface of the second interposer, one or more electrical connections in the second interposer, one or more through silicon vias in the second surface of the second interposer, and one or more solder bumps.

In one embodiment, the plurality of capacitors comprises one or more integrated deep trench capacitors.

In one embodiment, forming the first interposer further comprises forming a second plurality of capacitors.

In one embodiment, the integrated circuit comprises a system on a chip.

In one embodiment, the first and second interposers are silicon interposers.

In another embodiment, the present disclosure includes an electronic circuit comprising a stacked interposer, the stacked interposer comprising: a first integrated circuit comprising a first plurality of pads coupled to a first plurality of solder bumps; a stacked interposer comprising a second plurality of pads coupled the first plurality of solder bumps, the stacked interposer further comprising: a first interposer having, formed in a first surface of the first interposer, a first plurality of electrical connections and a first plurality of through silicon vias coupled to the first plurality of solder bumps; and a second interposer having, formed in a first surface of the second interposer, a second plurality of electrical connections and a second plurality of through silicon vias; and a second plurality of solder bumps coupled to the second plurality of through silicon vias.

In one embodiment, the first interposer comprises a plurality of capacitors.

In one embodiment, the first surface of the first interposer is bonded to the first surface of the second interposer.

In one embodiment, the first surface of the first interposer is bonded to the first surface of the second interposer using solder bumps.

In one embodiment, the present disclosure includes an electronic circuit comprising: a first integrated circuit comprising one or more processors and a first plurality of pads coupled to a first plurality of solder bumps; a stacked interposer comprising a first plurality of pads coupled the first plurality of solder bumps, the stacked interposer further comprising: a second integrated circuit comprising: a plurality of electrical connections; and a first plurality of vias coupled to a second plurality of solder bumps; and a third integrated circuit comprising: a plurality of capacitors; a plurality of electrical connections between the capacitors; a second plurality of vias coupled to the first plurality of vias of the second integrated circuit; and a second plurality of through silicon vias coupled to a second plurality of solder bumps.

In one embodiment, the second integrated circuit comprises a plurality of capacitors.

In another embodiment, the present disclosure includes a method of manufacturing an electronic circuit comprising: forming an interposer comprising the steps of: forming through silicon vias in the interposer; and forming vias on a first surface of the interposer; forming an integrated passive device comprising the steps of: forming capacitors and electrical connections in the integrated passive device; and forming vias on a first surface of the integrated passive device; bonding the vias on first surface of the interposer to the vias on the first surface of the integrated passive device; removing a portion of a second surface of the integrated passive device substrate; forming through silicon vias in the second surface; coupling an integrated circuit to the through silicon vias using solder bumps.

In another embodiment, the present disclosure includes stacked interposer means for stabilizing power signals in an electronic circuit.

In another embodiment, the present disclosure includes method of manufacturing an electronic circuit comprising steps for forming stacked interposer means for stabilizing power signals in an electronic circuit.

In another embodiment, the present disclosure includes an electronic circuit comprising a stacked interposer, the stacked interposer comprising: a first integrated electronic circuit comprising a first plurality of pads coupled to a first plurality of solder bumps; a stacked interposer comprising a second plurality of pads coupled the first plurality of solder bumps, the stacked interposer further comprising: a first interposer having, formed in a first surface of the first interposer, a first plurality of electrical connections and a first plurality of through silicon vias coupled to the first plurality of solder bumps; and a second interposer having, formed in a first surface of the second interposer, a second plurality of electrical connections and a second plurality of through silicon vias; and a second plurality of solder bumps coupled to the second plurality of through silicon vias.

In another embodiment, the present disclosure includes an electronic circuit comprising a stacked interposer, the stacked interposer comprising: a first interposer having. formed in a first surface of the first interposer, a first plurality of electrical connections and a first plurality of through silicon vias coupled to a first plurality of solder bumps; and a second interposer having, formed in a first surface of the second interposer, a second plurality of electrical connections and a second plurality of through silicon vias coupled to a second plurality of solder bumps, wherein the first plurality of solder bumps are bonded to the first surface of the second interposer and coupled to at least a portion of the second plurality of electrical connections.

In another embodiment, the present disclosure includes an electronic circuit comprising a stacked interposer, the stacked interposer comprising: a first interposer integrated circuit comprising: a first plurality of electrical connections proximate to a first surface of the first interposer integrated circuit; and a first plurality of vias; and a second interposer integrated circuit comprising: a second plurality of electrical connections proximate to a first surface of the second interposer integrated circuit; and a second plurality of vias, wherein the first surface of the first interposer integrated circuit and the first surface of the second interposer integrated circuit are coupled together to form said stacked interposer, and the first and second plurality of electrical connections are coupled to a plurality of integrated circuits bonded on top of the stacked interposer.

The above description illustrates various embodiments along with examples of how aspects of some embodiments may be implemented. The above examples and embodiments should not be deemed to be the only embodiments, and are presented to illustrate the flexibility and advantages of some embodiments as defined by the following claims. Based on the above disclosure and the following claims, other arrangements, embodiments, implementations and equivalents may be employed without departing from the scope hereof as defined by the claims.

What is claimed is:

1. An electronic circuit comprising:
a first integrated circuit comprising one or more processors and a first plurality of pads coupled to a first plurality of solder bumps;
a stacked interposer comprising a first plurality of pads coupled the first plurality of solder bumps, the stacked interposer further comprising:
a second integrated circuit comprising:
a first plurality of electrical connections; and
a first plurality of though silicon vias coupled between the first plurality of pads and the plurality of electrical connections; and
a first plurality of vias coupled to the plurality of electrical connections; and
a third integrated circuit comprising:
a second plurality of electrical connections;
a second plurality of vias coupled to the first plurality of vias of the second integrated circuit; and
a second plurality of through silicon vias coupled between the second plurality of electrical connections and a second plurality of pads.

2. The electronic circuit of claim 1, wherein the second integrated circuit further comprises a plurality of capacitors.

3. The electronic circuit of claim 2, wherein plurality of capacitors are coupled to power supply terminals of the first integrated circuit.

4. The electronic circuit of claim 3, wherein at least one power supply terminal of the first integrated circuit is coupled to one or more of the second plurality of pads, one or more of the second plurality of through silicon vias, one or more electrical connections of the second plurality of electrical connections, one or more of the second plurality of vias, one or more of the first plurality of vias, one or more of the first plurality of electrical connections, one or more of the plurality of capacitors, one or more of the first plurality of through silicon vias, and one or more of the first plurality of solder bumps.

5. The electronic circuit of claim 2, wherein the plurality of capacitors comprises one or more integrated deep trench capacitors.

6. The electronic circuit of claim 2, wherein the third integrated circuit further comprises a second plurality of capacitors.

7. The electronic circuit of claim 1, wherein the first integrated circuit is a system on a chip.

8. A method of manufacturing an electronic circuit comprising:
forming a first interposer comprising the steps of:
forming through silicon vias in the first interposer; and
forming vias on a first surface of the first interposer;
forming a second interposer comprising the steps of:
forming electrical connections in the second interposer; and
forming vias on a first surface of the second interposer;
bonding the vias on first surface of the first interposer to the vias on the first surface of the second interposer;
removing a portion of a second substrate surface of the second interposer;
forming through silicon vias in the second substrate surface of the second interposer;
coupling an integrated circuit to the through silicon vias of the second interposer using solder bumps.

9. The method of claim 8, further comprising:
after forming through silicon vias in the second surface of the second interposer,
removing a portion of a second substrate surface of the first interposer; and
forming second solder bumps on the second substrate surface of the first interposer.

10. The method of claim 8, wherein forming the second interposer comprises forming a plurality of capacitors.

11. The method of claim 10, wherein the plurality of capacitors is coupled to power terminals of the integrated circuit.

12. The method of claim 11, wherein at least one power terminal of the integrated circuit is electrically coupled to one or more through silicon vias in the first interposer, one or more vias on the first surface of the first interposer, one or more vias on the first surface of the second interposer, one or more electrical connections in the second interposer, one or more through silicon vias in the second surface of the second interposer, and one or more solder bumps.

13. The method of claim 10, wherein the plurality of capacitors comprises one or more integrated deep trench capacitors.

14. The method of claim 10, wherein forming the first interposer further comprises forming a second plurality of capacitors.

15. The method of claim 8, wherein the integrated circuit comprises a system on a chip.

16. The method of claim 8, wherein the first and second interposers are silicon interposers.

17. An electronic circuit comprising a stacked interposer, the stacked interposer comprising:
a first integrated circuit comprising a first plurality of pads coupled to a first plurality of solder bumps;
a stacked interposer comprising a second plurality of pads coupled the first plurality of solder bumps, the stacked interposer further comprising:
a first interposer having, formed in a first surface of the first interposer, a first plurality of electrical connections and a first plurality of through silicon vias coupled to the first plurality of solder bumps; and
a second interposer having, formed in a first surface of the second interposer, a second plurality of electrical connections and a second plurality of through silicon vias; and
a second plurality of solder bumps coupled to the second plurality of through silicon vias.

18. The electronic circuit of claim 17, wherein the first interposer comprises a plurality of capacitors.

19. The electronic circuit of claim 17, wherein the first surface of the first interposer is bonded to the first surface of the second interposer.

20. The electronic circuit of claim 17, wherein the first surface of the first interposer is bonded to the first surface of the second interposer using solder bumps.
